(19) United States
(12) Patent Application Publication
(10) Pub. No.: US 2025/0174489 A1
(43) Pub. Date: May 29, 2025

(54) FORMING OF TRENCHES IN A SUBSTRATE

(71) Applicants: COMMISSARIAT A L'ENERGIE ATOMIQUE ET AUX ENERGIES ALTERNATIVES, Paris (FR); STMicroelectronics (Crolles 2) SAS, Crolles (FR)

(72) Inventors: Thierry BERGER, BRIGNOUD (FR); Jerome DUBOIS, Grenoble (FR); Yann ESCARABAJAL, Grenoble (FR); Patrick GROS D'AILLON, Grenoble (FR)

(73) Assignees: COMMISSARIAT A L'ENERGIE ATOMIQUE ET AUX ENERGIES ALTERNATIVES, Paris (FR); STMicroelectronics (Crolles 2) SAS, Crolles (FR)

(21) Appl. No.: 18/191,617

(22) Filed: Mar. 28, 2023

(30) Foreign Application Priority Data
Sep. 21, 2022 (FR) 2209522

(51) Int. Cl. H01L 21/762; H01L 21/306; H01L 21/3065; H01L 27/146

(52) U.S. Cl. CPC H01L 21/76224; H01L 21/30608; H01L 21/3065; H10F 39/807

(57) ABSTRACT

The disclosure concerns a method including the steps of: a) providing a structure comprising a semiconductor substrate and, on the side of a first surface of the substrate, at least one first trench filled with an insulating material, vertically extending in the substrate; b) forming, by anisotropic etching from a second surface of the semiconductor substrate opposite to the first surface, at least one second trench vertically extending in the substrate and emerging onto the at least one first trench; and c) widening the at least one second trench by isotropic etching.

### CROSS-REFERENCE TO RELATED APPLICATION(S)

This application claims the priority benefit of French patent application number 2209522, filed on Sep. 21, 2022, entitled “Formation de tranchées dans un substrat”, which is hereby incorporated by reference to the maximum extent allowable by law.

### BACKGROUND

### Technical Background

The present disclosure generally concerns the field of electronic devices and, more precisely, methods of forming trenches in a substrate.

### Description of the Related Art

Many electronic device manufacturing methods comprise at least one step of forming of one or a plurality of trenches in a substrate. In the example of a method of manufacturing an image sensor comprising an array of pixels formed inside and on top of a semiconductor substrate, insulating trenches filled with a dielectric material may be formed between the pixels to electrically and/or optically insulate each pixel from the neighboring pixels.

### BRIEF SUMMARY

There is a need to improve current methods of forming of trenches in a substrate.

An embodiment overcomes all or part of the disadvantages of known methods of forming of trenches in a substrate.

For this purpose, an embodiment provides a method comprising the following steps:
a) providing a structure comprising a semiconductor substrate and, on the side of a first surface of the substrate, at least one first trench filled with an insulating material, vertically extending in the substrate;
b) forming, by anisotropic etching from a second surface of the semiconductor substrate opposite to the first surface, at least one second trench vertically extending in the substrate and emerging onto said at least one first trench; and
c) widening said at least one second trench by isotropic etching.

According to an embodiment, the etching of step a) is a reactive ion etching.

According to an embodiment, the etching of step b) is a chemical etching.

According to an embodiment, the etching of step b) is an etching in gaseous or liquid phase.

According to an embodiment, the method further comprises, after step c), a step d) of filling of said at least one second trench.

According to an embodiment, at step d), sides and a bottom of said at least one second trench are coated with at least one passivation layer.

According to an embodiment, said at least one passivation layer is coated with at least one reflective dielectric layer.

According to an embodiment, at step d), said at least one second trench is further filled with one or a plurality of metals.

According to an embodiment, said at least one second trench is intended to insulate a pixel of an image sensor from neighboring pixels.

According to an embodiment, said at least one second trench has, at the end of step b), an aspect ratio in the order of thirty.

According to an embodiment, said at least one second trench has, at the end of step c), an aspect ratio in the order of ten.

### BRIEF DESCRIPTION OF THE SEVERAL VIEWS OF THE DRAWINGS

The foregoing and other features and advantages of the present disclosure will be discussed in detail in the following non-limiting description of specific embodiments in connection with the accompanying drawing, in which:

FIG. 1 is a simplified and partial cross-section view showing an example of a structure comprising a substrate having trenches formed therein; and

FIG. 2A, FIG. 2B, and FIG. 2C are simplified and partial cross-section views illustrating successive steps of a method of forming trenches in a substrate according to an embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the applications where a structure comprising at least one trench formed in a substrate may be provided have not been detailed, the described embodiments and variants being compatible with usual applications implementing structures comprising one or a plurality of trenches formed in a substrate.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

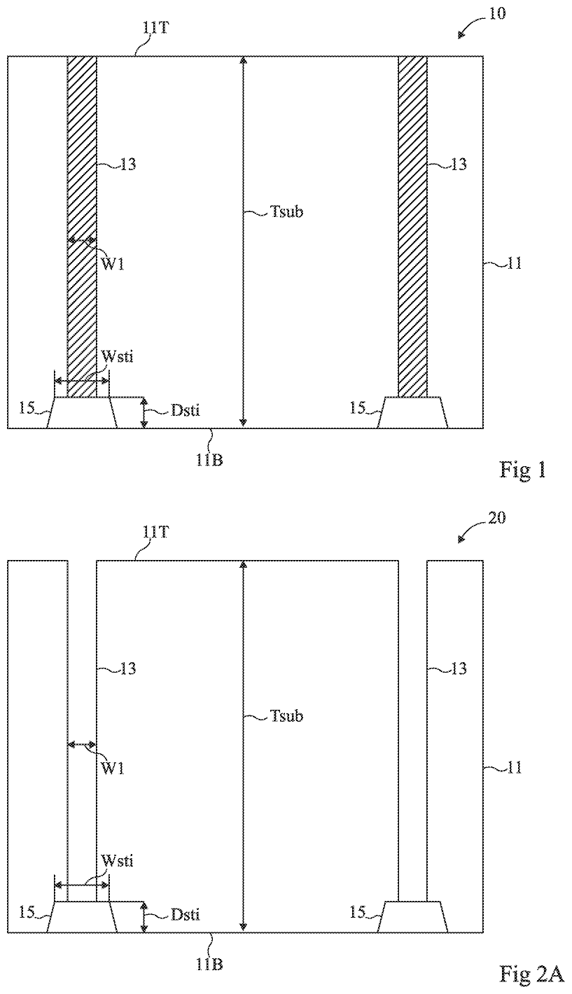

FIG. 1 is a simplified and partial cross-section view showing an example of a structure 10 comprising a substrate 11 having trenches 13 formed therein.

Substrate 11 is for example a wafer or a piece of wafer made of a semiconductor material, for example, silicon. As a variant, substrate 11 may comprise at least one layer of a semiconductor material formed, for example by epitaxy, on top and in contact with an upper surface of a support, not shown in FIG. 1. Substrate 11 for example has a thickness Tsub in the order of 6 μm.

In the shown example, trenches 13 extend vertically across the thickness of substrate 11 from a surface 11T of substrate 11 (the upper surface of substrate 11, in the orientation of FIG. 1). In this example, trenches 13 stop across the thickness of substrate 11 and do not emerge onto another surface 11B of substrate 11 (the lower surface of substrate 11, in the orientation of FIG. 1), opposite to surface 11T. In other words, each trench 13 has a depth, corresponding to a dimension of the trench measured along a direction orthogonal to surface 11T of substrate 11, smaller than the thickness Tsub of substrate 11. Surfaces 11B and 11T of substrate 11 are for example substantially parallel to each other.

In the shown example, trenches 13 have sides substantially orthogonal to surface 11T of substrate 11. Each trench 13 has a width W1, corresponding to a dimension of the trench measured along a lateral direction parallel to surface 11T of substrate 11, for example, equal to approximately 200 nm. In this example, each trench 13 has an aspect ratio (AR) in the order of thirty. In the present disclosure, the expression “aspect ratio” designates a ratio of the depth to the width of a trench. Generally, each trench 13 has an aspect ratio for example in the range from ten to eighty.

In the example illustrated in FIG. 1, trenches 13 are integrally filled with at least one material flush with surface 11T of substrate 11. In FIG. 1, the filling of trenches 13 has not been detailed and is symbolized by hatched blocks.

According to an example of embodiment, structure 10 forms part of an image sensor comprising an array of pixels formed inside and on top of substrate 11, each pixel for example more precisely comprising a photosensitive area formed in substrate 11 and laterally bordered with trenches 13. As an example, trenches 13 form a deep trench insulation (DTI) forming, in top view, a grid delimiting the photosensitive areas of the pixels of the image sensor integrating structure 10. Trenches 13 for example enable to electrically and optically insulate each pixel from the neighboring pixels.

In the shown example, structure 10 further comprises other trenches 15 extending vertically across the thickness of substrate 11 from surface 11B of substrate 11. Trenches 15 stop across the thickness of substrate 11 and do not emerge onto surface 11T of substrate 11. In other words, each trench 15 has a depth Dsti, corresponding to a dimension of the trench measured along a direction orthogonal to surface 11B of substrate 11, smaller than the thickness Tsub of substrate 11, for example equal to approximately 350 nm.

In the example illustrated in FIG. 1, trenches 15 have a flared cross-section. In other words, trenches 15 have sides oblique with respect to surface 11B of substrate 11. Trenches 15 more precisely have a larger width in the vicinity of surface 11B of the substrate 11 than in the vicinity of their bottom, that is, in the vicinity of trenches 13. The bottom of each trench 15 for example has a width Wsti equal to approximately 500 nm.

In the shown example, trenches 15 are integrally filled with an electrically-insulating material, for example, silicon dioxide, flush with surface 11B of substrate 11. As an example, trenches 15 form a shallow trench insulation (STI).

In the illustrated example, each trench 13 is located vertically in line with one of trenches 15 and the bottom of each trench 13 emerges onto the bottom of the underlying trench 15. The filling material(s) of each trench 13 are located on top of and in contact with the filling material(s) of the underlying trench 15.

In the example of embodiment where structure 10 forms part of an image sensor comprising an array of pixels formed inside and on top of substrate 11, trenches 15 for example form part of a readout circuit, not detailed in FIG. 1, of the sensor pixels. As an example, the readout circuit comprises readout transistors and an interconnection structure formed inside and on top of substrate 11, on the side of surface 11B of substrate 11. In this example, the image sensor integrating structure 10 is called backside illumination (BSI) sensor, that is, the sensor pixels are illuminated from the surface 11T of substrate 11 opposite to the surface 11B on the side of which are formed the interconnection structure and trenches 15.

According to an example of embodiment, trenches 13 are formed by photolithography and then etching from surface 11T of substrate 11 after steps of forming and of filling of trenches 15 in substrate 11 from surface 11B. In this example, the filling material of trenches 15 plays the role of an etch stop layer during the forming of trenches 13. In practice, trenches 13 may slightly penetrate into the thickness of the filling material of trenches 15, for example across a thickness in the range from a few nanometers to a few tens of nanometers.

In the example illustrated in FIG. 1, trenches 13 are aligned with respect to trenches 15. However, misalignments capable of ranging up to approximately 150 nm may cause an offset of trenches 13 with respect to trenches 15. Further, the speed of etching of trenches 13 may be non-uniform along a same trench. Further, the speed of etching of trenches 13 may depend on the density of trenches (number of trenches per surface area unit) and may further vary according to the location of the trenches with respect to substrate 11, where the etching speed may for example be greater close to the edge(s) of substrate 11 than at its center, or conversely. The speed of etching of trenches 13 may further be more significant at the intersections of trenches 13. Certain portions of the bottom of one or a plurality of trenches 13 may thus more rapidly reach the filling material of trenches 15 than other portions of the bottom of this or these trench(es) during the etching.

It is for example desirable to form trenches 13 having the smallest possible width W1 to optimize the space available for the photodiodes and the transistors of the pixels of the image sensor. Width W1 depends on thickness Tsub of substrate 11 and is a function of performances of an etching reactor implementing the method of etching of trenches 13.

To avoid any risk of damage to elements located on the side of surface 11B of substrate 11, for example, the readout circuit, during the step of etching of trenches 13, width Wsti is adapted to compensate for a possible misalignment, for example, in the order of 150 nm, between trenches 13 and 15. This enables to guarantee that the bottom of each trench 13 only emerges onto one of trenches 15 and to avoid for trenches 13 to emerge, even partially, onto surface 11B of substrate 11. For a width W1 equal to approximately 200 nm, width Wsti will for example be selected to be equal to approximately 500 nm (W1+2×150 nm).

A disadvantage of structure 10 lies in the fact that trenches 13 have a high aspect ratio. This induces problems of filling of trenches 13. More precisely, the number and the thickness of the layers used to fill trenches 13, as well as the implemented deposition techniques, are limited according to the small width W1 of trenches 13. To overcome this problem, a solution might consist in decreasing the aspect ratio of trenches 13. This would however require increasing the width W1 of trenches 13, which is not desirable since this would result in undesirable constraints in terms of sizing of the sensor pixels, for example due to the need to increase the width Wsti of trenches 15, to avoid for trenches 13 to emerge, even partially, onto surface 11B of substrate 11, which would result in decreasing the space available for the photodiodes and the transistors of the pixels. As an example, a widening of trenches 15 would negatively impact the pixel performance by inducing a decrease in the size of the readout transistors on the side of surface 11b of the substrate (noise increase) or a decrease in the size of the photosensitive diode of the pixel and thus on the pixel charge at saturation (signal decrease) or would require, for an equivalent resolution and performance, an increase in the pixel size, inducing an excess cost for the user.

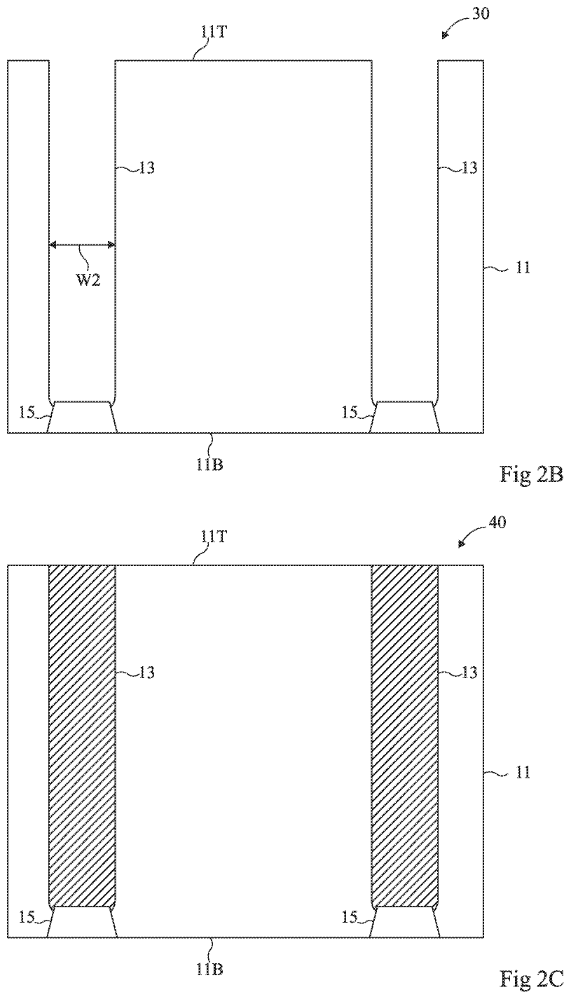

FIG. 2A, FIG. 2B, and FIG. 2C are simplified and partial cross-section views illustrating successive steps of a method of forming trenches in a substrate according to an embodiment.

FIG. 2A more precisely illustrates a structure 20 similar to the structure 10 previously described in relation with FIG. 1.

The structure 20 of FIG. 2A differs from the structure 10 of FIG. 1 in that, in the structure 20 of FIG. 2A, trenches 13 are not filled.

According to an embodiment, the structure 20 of FIG. 2A is obtained at the end of the following successive steps:
a) providing a structure comprising semiconductor substrate 11 and, on the side of surface 11B of the substrate, trenches 15 filled with an insulating material and vertically extending in substrate 11; and
b) forming, by anisotropic etching from surface 11T of substrate 11, trenches 13 vertically extending in substrate 11 and emerging onto trenches 15.

In the present description, the expression “anisotropic etching” designates an etch technique having a much higher etching speed, for example, one thousand times higher, in certain directions of space than in others. More precisely, in the shown example, the etch speed is much higher in a direction perpendicular to surface 11T of substrate 11 than in directions parallel to surface 11T of substrate 11. As an example, the etching speed in directions parallel to surface 11T of substrate 11 is much smaller, for example, one thousand times smaller, than that in directions orthogonal to surface 11T, or even substantially zero. The sides of trenches 13 are thus, during the anisotropic etch step, etched at a speed smaller than the speed of etching of the bottom of trenches 13.

In the example illustrated in FIG. 2A, structure 20 comprises two trenches 13, each emerging onto an underlying trench 15. This example is however not limiting, those skilled in the art being capable of providing any number of trenches 13, each emerging onto an underlying trench 15.

As an example, trenches 13 are formed by photolithography and then reactive ion etching (RIE), for example, more precisely by deep reactive ion etching (DRIE).

FIG. 2B illustrates a structure 30 obtained after implementation of an isotropic etch step aiming at widening the trenches 13 of the structure 20 of FIG. 2A.

In the present description, the expression “isotropic etching” designates an etching technique having a substantially identical etching speed whatever the considered direction of space. More precisely, in the shown example, the etching speed along the direction perpendicular to surface 11T of substrate 11 is substantially equal to the etching speed along the directions parallel to surface 11T of substrate 11. The sides and the bottom of trenches 13 are thus, during the isotropic etch step, substantially etched at the same speed.

As an example, the isotropic etching is a chemical etching, for example, more precisely an etching in gaseous phase comprising fluorine radicals. The isotropic etching implemented is selective over silicon dioxide or over any other material for filling trenches 15. As a variant, the chemical etching may be an etching in liquid phase.

In the example illustrated in FIG. 2B, trenches 13 have, after the isotropic etching, a width W2 greater than the width W1 obtained after the step of anisotropic etching previously described in relation with FIG. 2A. As an example, width W2 is equal to approximately 600 nm. In an example where the thickness Tsub of substrate 11 is equal to approximately 6 μm, the aspect ratio of trenches 13 is, after isotropic etching, in the order of ten. More generally, the aspect ratio of trenches 13 is, after isotropic etching, for example in the range from five to sixty.

FIG. 2C more precisely illustrates a structure 40 obtained after implementation of one or a plurality of steps of filling of the trenches 13 of the structure 30 of FIG. 2B. In FIG. 2C, the filling of trenches 13 has not been detailed and is symbolized by hatched blocks.

As an example, the sides and the bottom of each trench 13 may be coated with a passivation layer, for example, a layer made of a dielectric material, for example, a charged dielectric material having fixed charges, intended to prevent for charges photogenerated in the photosensitive areas of the pixels to be trapped at the interface between trenches 13 and substrate 11, which would result in a signal loss. The passivation layer is further intended to avoid the spontaneous forming of electron-hole pairs at the interface between trenches 13 and substrate 11, these pairs being likely to cause a dark current disturbing the measurement signal. The passivation layer for example further enables to electrically insulate each pixel from the neighboring pixels to avoid for charges photogenerated in a photosensitive area of a pixel to be able to transit to a photosensitive area of an adjacent pixel. As an example, the passivation layer is made of a material having a dielectric constant greater than that of silicon dioxide, for example, an aluminum-doped hafnium oxide (Al:HfO₂).

The passivation layer of trenches 13 may further be coated with a layer or with a stack of dielectric layers intended to reflect, towards the photosensitive areas of the pixels, the incident light illuminating the sensor from surface 11T of substrate 11. This enables for example to optically insulate each pixel from the neighboring pixels and to obtain an increased photoconversion efficiency. As an example, in the case of a stack, the layers located close to the sides of trenches 13 may have a refraction index greater than that of the layers located in the vicinity of a central region of trenches 13.

The central region of each trench 13 is for example filled with air. As a variant, the central region of each trench 13 may be filled with one or a plurality of metals, for example, selected from among tungsten, aluminum, and copper, or metal alloys.

An advantage of the method described hereabove in relation with FIGS. 2A to 2C lies in the fact that it enables to obtain trenches 13 wider than those of the structure 10 of FIG. 1. This provides more possibilities in terms of filling of trenches 13 while avoiding for trenches 13 to emerge, even partially, onto surface 11B of substrate 11. Further, the trenches obtained according to this method advantageously enable to achieve a quantum efficiency greater than that obtained by the trenches of FIG. 1, as well as a lower optical crosstalk.

Various embodiments and variants have been described. Those skilled in the art will understand that certain features of these various embodiments and variants may be combined, and other variants will occur to those skilled in the art. In particular, the described embodiments are not limited to the specific examples of materials and of dimensions mentioned in the present disclosure.

Finally, the practical implementation of the described embodiments and variants is within the abilities of those skilled in the art based on the functional indications given hereabove.

Method of forming trenches (13, 15) in a semiconductor substrate (11) may be summarized as including the following steps: a) providing a structure (20) including the semiconductor substrate (11) and, on the side of a first surface (11B) of the substrate, at least one first trench (15) filled with an insulating material, vertically extending in the substrate; b) forming, by anisotropic etching from a second surface (11T) of the semiconductor substrate opposite to the first surface (11B), at least one second trench (13) vertically extending in the substrate and emerging onto said at least one first trench (15); and c) widening said at least one second trench (13) by isotropic etching.

The etching of step b) may be a reactive ion etching.

The etching of step b) may be a chemical etching.

The etching of step b) may be an etching in gaseous or liquid phase.

Method may further include, after step c), a step d) of filling of said at least one second trench (13).

At step d), sides and a bottom of said at least one second trench (13) may be coated with at least one passivation layer.

Said at least one passivation layer may be coated with at least one reflective dielectric layer.

At step d), said at least one second trench (13) may be further filled with one or a plurality of metals.

Said at least one second trench (13) may be intended to insulate a pixel of an image sensor from neighboring pixels.

Said at least one second trench (13) may have, at the end of step b), an aspect ratio in the order of thirty.

Said at least one second trench (13) may have, at the end of step c), an aspect ratio in the order of ten.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
forming trenches in a semiconductor substrate, on a side of a first surface of the substrate by:
filling at least one first trench with an insulating material, vertically extending in the substrate;
forming, by anisotropic etching from a second surface of the semiconductor substrate opposite to the first surface, at least one second trench vertically extending in the substrate and emerging onto the at least one first trench; and
widening the at least one second trench by isotropic etching.

2. The method according to claim 1, wherein the etching from the second surface is a reactive ion etching.

3. The method according to claim 1, wherein the etching from the second surface is a chemical etching.

4. The method according to claim 1, wherein the etching of from the second surface is an etching in gaseous or liquid phase.

5. The method according to claim 1, comprising, after widening, filling of the at least one second trench.

6. The method according to claim 5, wherein, the filling of the at least one second trench includes coating sides and a bottom of the at least one second trench with at least one passivation layer.

7. The method according to claim 6, comprising coating the at least one passivation layer with at least one reflective dielectric layer.

8. The method according to claim 5, wherein, the filling of the at least one second trench includes filling with one or a plurality of metals.

9. The method according to claim 1, wherein the at least one second trench is intended to insulate a pixel of an image sensor from neighboring pixels.

10. The method according to claim 1, wherein the at least one second trench has, at the end the etching includes an aspect ratio in the order of thirty.

11. The method according to claim 1, wherein the at least one second trench has, at the end of the widening an aspect ratio in the order of ten.

12. A device, comprising:
a substrate having a first surface opposite to a second surface;
a first trench in the first surface;
a second trench in the second surface and overlapping with an end of the first trench.

13. The device of claim 12, wherein the first trench has a first dimension into the substrate and the second trench has a second dimension into the substrate, the first dimension being greater than the second dimension.

14. The device of claim 13, wherein the first trench includes an insulating material.

15. The device of claim 14, wherein the second trench includes a metal layer.

16. The device of claim 15, wherein the second trench includes a passivation layer.

17. A device, comprising:
a semiconductor substrate having a first surface opposite to a second surface;
a first trench in the first surface that includes an insulating material, the first trench having a first end that is closer to the second surface than the first surface;
a second trench in the second surface that includes a conductive material, the second trench having a second end that abuts the first end of the first trench.

18. The device of claim 17, wherein the conductive material is metal.

19. The device of claim 18, wherein the second trench includes a passivation layer.
